(19) United States
(12) Patent Application Publication
(10) Pub. No.: US 2002/0105779 A1
(43) Pub. Date: Aug. 8, 2002

(54) Cooling system of a computer chassis

(76) Inventors: Pei-Chih Lei, Chungho City (TW); Chi-Huan Chuang, Chungho City (TW); Chun-Chieh Pan, Chungho City (TW)

Correspondence Address: Alan Kamrath, RIDER BENNETT EGAN & ARUNDEL, LLP, Suite 2000, 333 South Seventh Street, Minneapolis, MN, 55402, US

(21) Appl. No.: 09/776,223

(22) Filed: Feb. 2, 2001

(51) Int. Cl. H05K 7/20; G06F 1/20

(52) U.S. Cl. 361/687; 361/683; 361/688; 361/700

(57) ABSTRACT

A cooling system for a computer chassis has a housing with a compressor, a condenser, an evaporator and tubes connecting the compressor, the condenser and the evaporator together to form a cycle. The computer chassis communicates with the housing by means of an air vent, such that air driven by a fan inside the housing flows into the chassis to cool down the temperature inside the chassis and the air is able to flow downward to the housing by means of an air inlet in the housing for processing by the cooling system.

### BACKGROUND OF THE INVENTION

1. Field of the Invention

The present invention relates to a cooling system for a computer chassis, and more particularly to a cooling system that has a condenser, a compressor and an evaporator. Tubes are used to connect the components to form a cycle, such that the heat generated from the central processing unit (CPU) and peripherals is effectively dissipated to protect the computer components from malfunctioning due to excessive heat.

2. Description of Related Art

To boost the overall speed of current computers, the speed of the CPU is greatly increased. To match the speed of newly developed CPUs, the speed of the dynamic random access memory (DRAM) also has to be upgraded to 100 MHZ, 133 MHZ or even higher. The increased performance of the other components, the increased size of hard disks and the reduced time to process hard disk queries has caused the hard disk speed to increase significantly and often reaches 7200 rpm. Higher revolution speed, shorter reaction time of the CPU, the DRAM and all the other peripherals mean that the heat generated in the computer has greatly increased. With the current heat dissipating apparatus in computers, there is no way to dissipate such a large amount of heat within seconds efficiently. According to analysis, about 37% of the total generated heat originates from the operation of the CPU. Thus, if the generated heat can not be dissipated effectively, the accuracy of the CPU will be seriously affected and sometimes the overheated CPU will lead to computer faults, failures or complete shutdown situation.

In order to cope with the more and more serious situation caused by the increasingly upgraded performance of the computer peripherals, the present invention intends to present an improved cooling system to solve the problems.

### SUMMARY OF THE INVENTION

The primary objective of the invention is to provide an improved cooling system for a computer chassis. The cooling system has a compressor, a condenser, an evaporator and tubes connecting the components together, such that the cool air generated from the cooling system is able to reduce the temperature inside the computer chassis efficiently.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of the cooling system in accordance with the present invention used in the computer chassis;

FIG. 2 is a side view in partial section of the cooling system and the computer chassis along line 2-2 in FIG. 1; and

FIG. 3 is a schematic cross sectional front view of the cooling system along line 3-3 in FIG. 1 showing the air flow through the cooling system, wherein in order to have a better understanding of the inside structure of the cooling system of the invention, the computer chassis is shown in phantom lines.

### DETAILED DESCRIPTION OF PREFERRED EMBODIMENT

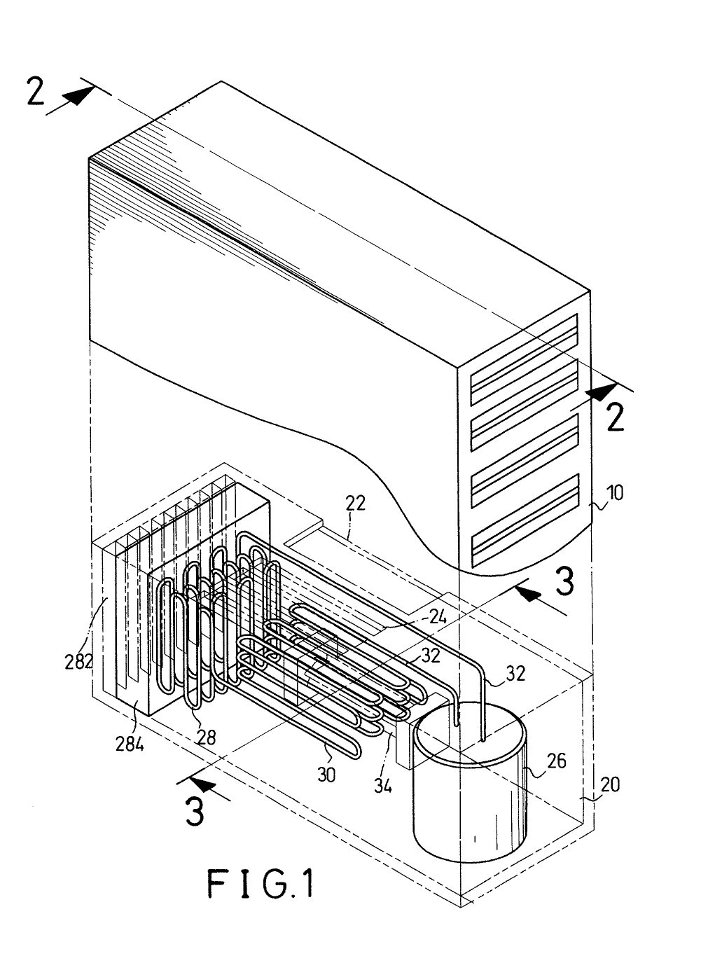

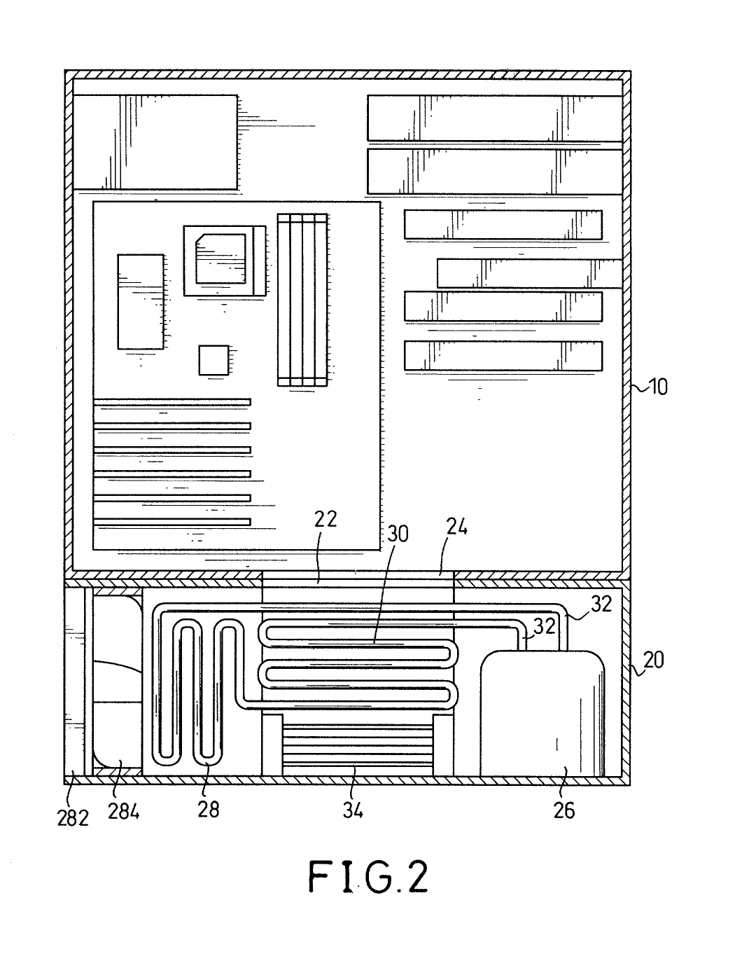

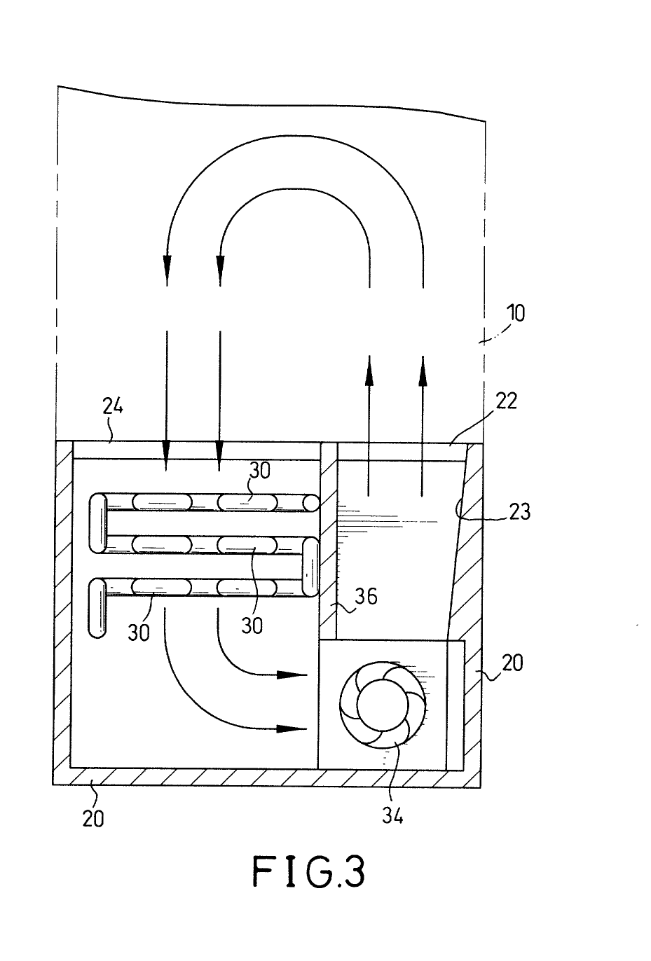

With reference to FIGS. 1, 2 and 3, the cooling system in accordance with the present invention has a housing (20) with a compressor (26), condenser (28), an evaporator (30) and tubes (32) connecting the foregoing components to form a cycle. A cooling fan (284) and fins (282) are mounted beside the condenser (28). With such an arrangement, the heat by the condenser is directed out of the casing (20) by the cooling fan. An air vent (22) and an air inlet (24) (shown in FIGS. 2 and 3) are defined in the top face of the casing (20) to communicate with the interior of the computer chassis (10). Furthermore, the cooling system of the invention has a fan (34) positioned below the vent (22) and an airway (23) defined by an inner side face of the housing (20) and a plate (36) so that the cool air is able to be directed by the fan (34) to the computer chassis (10) through the airway (23).

When the cooling system is in operation, the compressor (26) will transmit the coolant inside the compressor (26) to the evaporator (30) and the condenser (28) by means of the tubes (32) to form a circular cycle. The suction force from the fan (34) will draw the heated air inside the computer chassis (10) to flow downward and into the housing (20) through the inlet (24). When the heated air inside the computer chassis (10) flows over the evaporator (30), the heat is removed from the air. The cooled air is then driven through the airway (23) by the fan (34) and inside the computer chassis (10), such that the cooled air is able to cool the components inside the computer chassis (10) to maintain the components in a stable operational condition. With the cooling system in accordance with the present invention, all the components that will generate heat are able to be cooled down in order to maintain the operational mode of the computer.

According to the foregoing description, the present invention has the advantages of efficiently cooling down the temperature inside the computer chassis and no modification to the current computer chassis being required.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A cooling system for a computer chassis comprising:
a housing adapted to communicate with the chassis and having a compressor, a condenser, an evaporator and tubes connecting the compressor, the condenser and the evaporator together to form a cycle; and
a fan located inside the housing to force the air to flow into the chassis.

2. The cooling system as claimed in claim 1, wherein the housing has an air vent and an air inlet defined to communicate with an interior of the chassis so that air driven by the fan is able to flow from the housing into the chassis, the air inside the chassis is able to flow into the housing through the inlet.

3. The cooling system as claimed in claim 2, wherein an airway is formed by an inner face of the housing and a plate and above the fan, such that air is able to be directed to the chassis through the airway.
